(19) United States
(12) Patent Application Publication
(10) Pub. No.: US 2014/0120729 A1
(43) Pub. Date: May 1, 2014

(54) METHOD FOR REMOVING A PATTERNED HARD MASK LAYER

(71) Applicant: TAIWAN SEMICONDUCTOR MANUFACTURING COMPANY, LTD., (US)

(72) Inventors: Yu-Lun Liu, Beidou Township (TW); Ying-Hao Su, Hsinhu City (TW); Chia-Chu Liu, Shin-Chu City (TW); Kuei-Shun Chen, Hsin-Chu (TW)

(21) Appl. No.: 13/666,268

(22) Filed: Nov. 1, 2012

(51) Int. Cl. H01L 21/308; G06F 17/50

(52) U.S. Cl. CPC H01L 21/3088; G06F 17/50
USPC 438/703; 716/55

(57) ABSTRACT

The present disclosure provides embodiments of a method that includes providing a substrate having a patterned material layer and a patterned hard mask layer disposed on the patterned material layer, wherein the patterned material layer includes a material feature having a first dimension and the patterned hard mask layer includes a hard mask feature covering the material feature. The method also includes forming, on the substrate and the hard mask feature, a patterned resist layer with an opening that exposes the hard mask feature and has a second dimension as a function of the first dimension; etching back the resist film; and removing the patterned hard mask layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC processing and manufacturing are needed.

### BRIEF DESCRIPTION OF THE DRAWINGS

The present disclosure is best understood from the following detailed description when read with accompanying figures. It is emphasized that, in accordance with the standard practice in the industry, various features are not drawn to scale and are used for illustration purpose only. In fact, the dimension of the various features may be arbitrarily increased or reduced for clarity of discussion.

FIG. 1 is a flow chart of a method for forming a pattern according to one or more embodiments.

FIGS. 2-6 are diagrammatic cross-sectional side views of a semiconductor structure formed according to the method of FIG. 1.

FIG. 7 is a flow chart of a method for removing a hard mask according to one or more embodiments of the present disclosure.

FIGS. 8-11 are diagrammatic cross-sectional side views of a semiconductor structure made according to the method of FIG. 7.

FIG. 12 is a scanning electron microscope (SEM) views and simulated profile of resist features.

FIG. 13 is a flow chart of a method for forming a mask according to one or more embodiments.

FIG. 14 is a table constructed according to various aspects of the present disclosure in one embodiment.

FIG. 15 is a diagrammatic cross-sectional side view of the of the semiconductor structure and the photomask of FIG. 9 in portion.

### DETAILED DESCRIPTION

For example, lithography processes often implement removing a hard mask layer on top of a polysilicon stack pattern. One of the challenges is that portions of the hard mask layer remain on top of the polysilicon stack pattern after the removal (e.g. etching) process. The remaining portions of the hard mask layer on top of the polysilicon stack pattern may require an extra rework, and may further impact the performance of the IC devices.

The following disclosure provides many different embodiments, or examples, for implementing different features of the invention. Specific examples of components and arrangements are described below to simplify the present embodiments. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

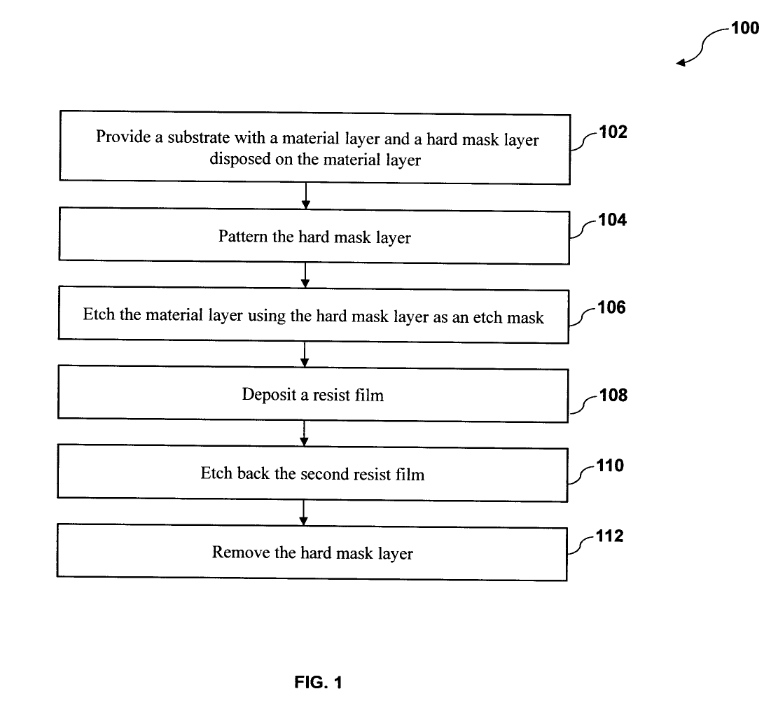

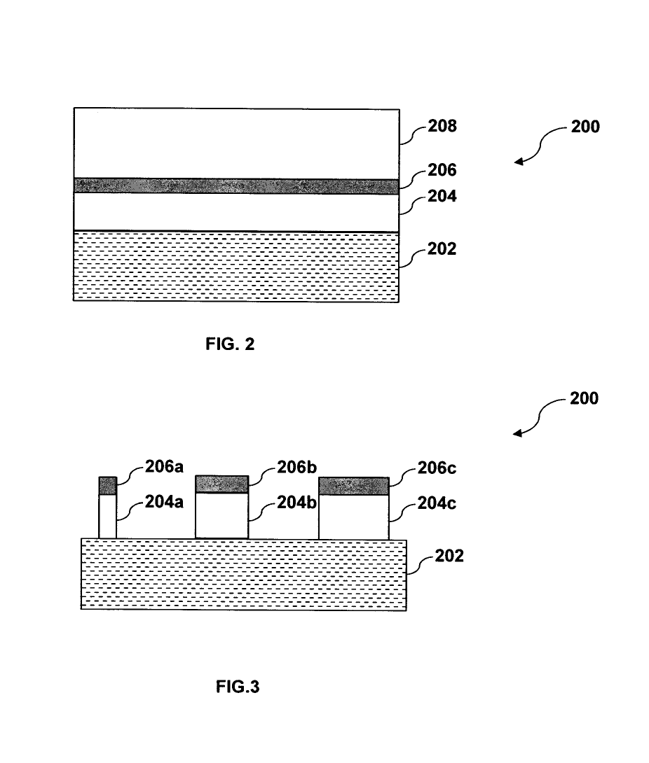

FIG. 1 is a flow chart of a method 100 of forming a semiconductor structure according to one or more embodiments of the present disclosure. FIGS. 2-6 are cross-sectional side views of a semiconductor structure 200 at different fabrication stages. The method 100 and the semiconductor structure 200 are collectively described with reference to FIGS. 1 through 7.

Referring to FIGS. 1 and 2, the method 100 begins at operation 102 by providing or receiving a substrate 202. In one example, the substrate 202 is a silicon wafer or other semiconductor wafer. A material layer 204 is disposed on the substrate 202 and a hard mask layer 206 is disposed on the material layer 204. In one embodiment, the material layer 204 includes a gate material layer. In furtherance of the embodiment, the material layer 204 includes a gate dielectric film and a gate electrode (or conductive) film. In various examples, the gate dielectric film includes silicon oxide, high k dielectric material or combination thereof. In other examples, the gate electrode film includes metal, polycrystalline silicon (polysilicon), or combination thereof. The hard mask layer 206 may include silicon oxide, silicon nitride, silicon carbide or other suitable material.

Referring to FIGS. 1 and 3, the method 100 proceeds to operation 104 by patterning the hard mask layer 206. In the present embodiment, the patterning of the hard mask layer 206 includes a lithography process and an etch process. In one embodiment, the lithography process includes coating, exposure, and developing.

A resist film 208 is coated on the hard mask layer 206. An exposure process is applied to the resist film 208 to form a latent image pattern on the resist film. Then a developing process is applied to the exposed resist film to form a patterned resist film (or resist pattern) with various openings defined therein.

In another embodiment, the lithography process includes coating, soft baking, exposure, post-exposure baking, developing and hard baking. In one example, the coating or depositing of the resist film is implemented by a spin-on coating process.

Then an etch process is applied to the hard mask layer 206 through the openings of the patterned resist film 208. Thus, the openings are transferred to the hard mask layer 206, resulting in a patterned hard mask layer 206. The etch process may include a wet chemical etching process or other suitable etch process. After the etch process, hard mask features 206a-c are formed on the material layer 204. In the example, the hard features 206a-c have different dimensions, representing three exemplary dimensions of a hard mask feature, such as the feature 206a with a small dimension, the feature 206b with a middle dimension, and the feature 206c with a large dimension. After the hard mask layer 206 is patterned, the resist film 208 may be removed by wet stripping or ashing.

Still referring to FIGS. 1 and 3, the method 100 proceeds to operation 106 by etching the material layer 204 using the hard mask layer 206 as an etch mask. The etch process may include a dry plasma etching process, or a wet chemical etching process, or a combination thereof. After the etch process, the material layer 204 is patterned to form various material features, such as material features 204a-204c. In the present embodiment, the material features 204a-204c includes various gate stacks for field-effect transistors (FETs), dummy gate or both. After the material layer 204 is patterned, the semiconductor structure 200 has an uneven surface profile.

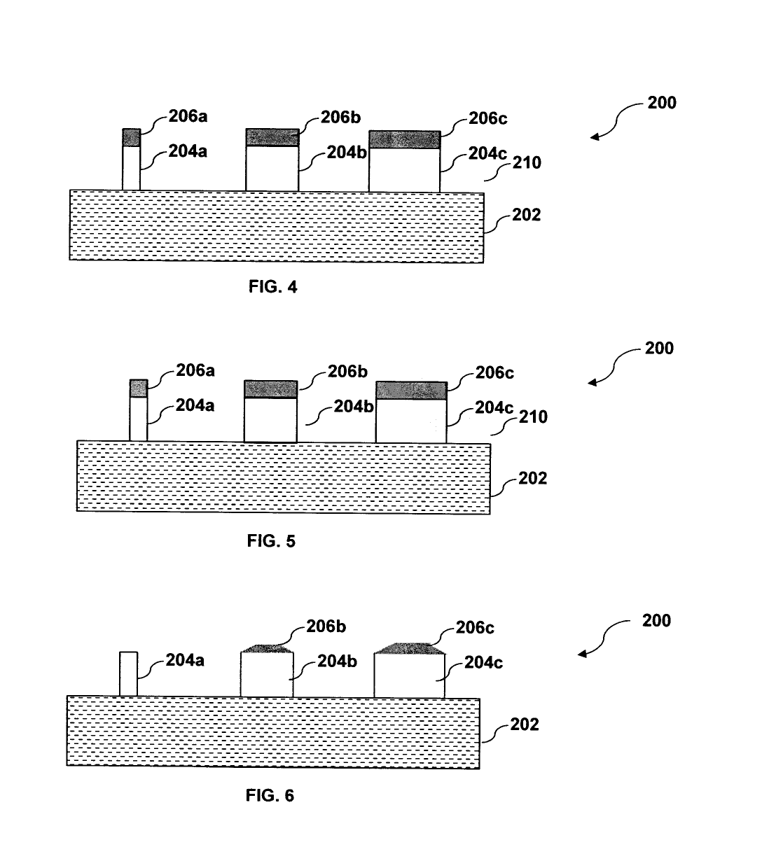

Referring to FIGS. 1 and 4, the method 100 proceeds to operation 108 to deposit another resist film 210 on the substrate 202, for example, by a spin-on process. Especially, the resist film 210 is also formed on the hard mask features 206a-c. As an example illustrated in FIG. 4, the material features 204a-c and the hard mask features 206a-c are buried in the resist film 210. It is noted that the resist film 210 has an uneven surface profile because of topography of the material feature 204a-c and the hard mask feature 206a-c. The operation 108 may include other step, such as soft baking to drive out the solvent of the resist film 210.

Referring to FIGS. 1 and 5, the method 100 proceeds to operation 110 for etching back the resist film 210 so that the thickness of the resist film 210 is reduced. By the etching back to the resists film 210, the hard mask features are uncovered by the resist film 210. The operation 114 may include a dry plasma etching process, or a wet chemical etching process, or both. As one example illustrated in FIG. 5, some small hard mask feature (such as 206b and 206c) may still be covered by the resist film 210 because of the poor uniformity of the resist film 210.

Referring to FIGS. 1 and 6, the method 100 proceeds to operation 112 for etching the hard mask layer 206. The operation 112 includes removing the hard mask layer 206 that includes various hard mask features (such as 206a, 206b and 206c). The operation 112 includes the dry plasma etching process and/or the wet chemical etching process. The operation 112 may further include a cleaning process. Additional operations may be implemented before, during, and after the method 100.

As illustrated as an example in FIG. 6, one or more hard mask features may not be completely removed by the etching process in the operation 112. For example, portions of the hard mask feature 206b and the hard mask feature 206c are still left on the material feature 204b and the material feature 204c, respectively. It is noted that the small hard mask feature 206a is removed from top of the small material feature 204a.

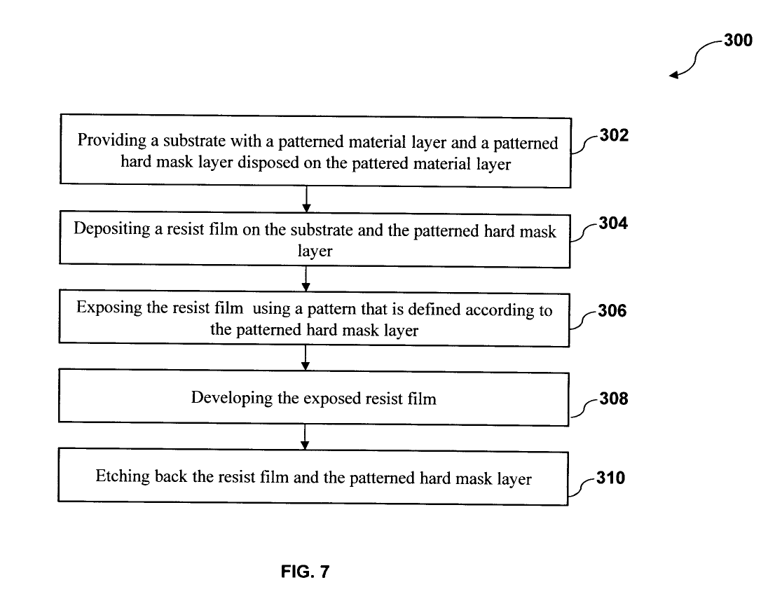

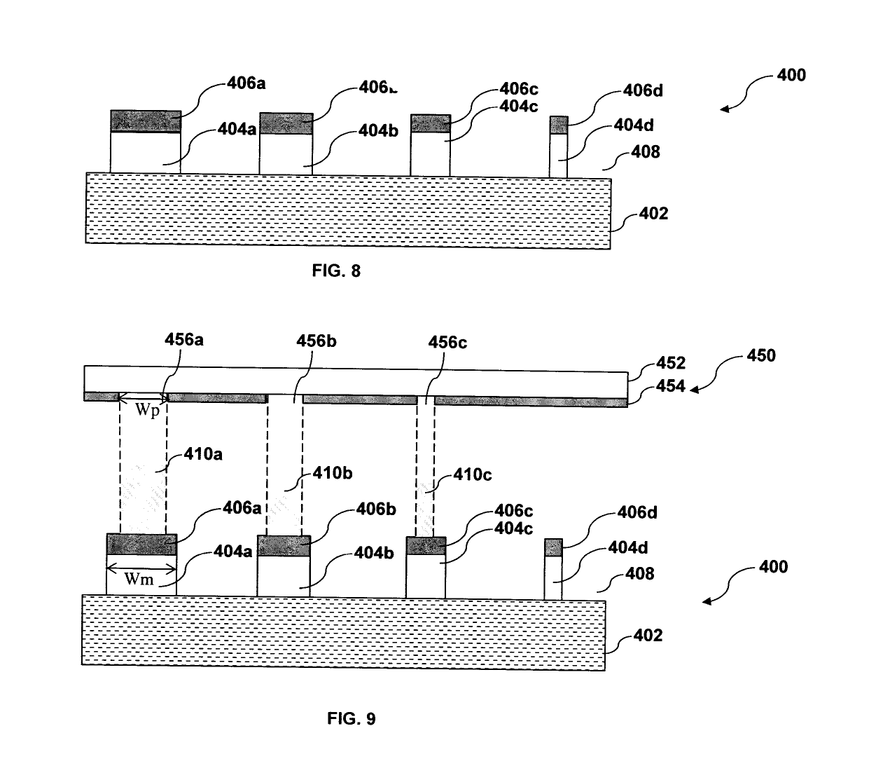

FIG. 7 is a flow chart of a method 300 for forming a semiconductor structure constructed according to another embodiment. FIGS. 8-11 illustrate cross-sectional views of device semiconductor structure 400 at different fabrication stages. The semiconductor structure 400 and the method 300 making the same are collectively described with reference to FIGS. 7 through 11.

Referring to FIGS. 7 and 8, the method 300 begins at operation 302 by providing or receiving a substrate 402 with a patterned material layer 404 and a patterned hard mask layer 406 disposed on the patterned material layer 404. In the present embodiments, the substrate 402 is similar to the substrate 202 and may include a wafer, such as a silicon wafer. Alternatively or additionally, the substrate 402 includes another elementary semiconductor, such as germanium; a compound semiconductor including silicon carbide, gallium arsenic, gallium phosphide, indium phosphide, indium arsenide, and/or indium antimonide; or an alloy semiconductor including SiGe, GaAsP, AlInAs, AlGaAs, GaInAs, GaInP, and/or GaInAsP. In yet another alternative, the substrate 402 includes a semiconductor on insulator (SOI) structure. The substrate 402 further includes various doped features, such as n-type wells and/or p-type wells, formed by ion implantation or diffusion. The substrate 402 also includes various isolation features, such as shallow trench isolation (STI), formed by a process, such as a process including etching to form various trenches and then depositing to fill the trench with a dielectric material.

In the present embodiments, the patterned material layer includes one or more conductive and/or dielectric films. In the present embodiment, the patterned material layer 404 includes a gate dielectric film having a dielectric material and a gate electrode film having a conductive material. The dielectric material for the gate dielectric film may include silicon oxide, high k dielectric material film, or a combination of silicon oxide and high k dielectric material. The conductive thin film for the gate electrode film may include doped polysilicon, or a metal, such as aluminum (Al), copper (Cu), tungsten (W), nickel (Ni), titanium (Ti), gold (Au), platinum (Pt) or alloy of the metals thereof. According to various embodiments. In other embodiments, the patterned hard mask layer 406 includes silicon oxide, silicon nitride, silicon carbide or other suitable materials. The patterned material layer 404 includes various material features, such as material features 404a-d illustrated in FIG. 8 as one example. The patterned hard mask layer 406 includes various hard mask features, such as hard mask features 406a-d, that are disposed on and define the material feature 404a-d, respectively.

The patterned material layer 404 and the patterned hard mask layer 406 may be formed by a procedure that includes depositing a material layer and a hard mask layer, patterning the hard mask layer, and patterning the material layer using the patterned hard mask layer as an etch mask. In one embodiment, the patterned material layer 404 and the patterned hard mask layer 406 are formed by a procedure that includes the operations 102, 104 and 106 of the method 100.

Still referring to FIGS. 7 and 8, the method 300 proceeds to operation 304 by depositing a resist film 408 on the substrate 402 and on the patterned hard mask layer 406 disposed on the patterned material layer 404, for example, by a spin-on coating process. In the present disclosure, a resist is also referred to as a photo resist. The operation 304 may include performing a dehydration process before applying the resist film on the substrate, which can enhance an adhesion of the first resist film to the substrate. The dehydration process may include baking the substrate at a high temperature for a period of time, or applying a chemical such as hexamethyldisilizane (HMDS) to the wafer substrate. The operation 304 may include a soft bake (SB), which can increase a mechanical strength of the resist film. The resist film 408 is deposited on the substrate 402 and the hard mask features 406a-d. In the present embodiment, the material features 404a-d and the hard mask feature 406a-d are buried in the resist film 408.

Referring to FIGS. 7 and 9, the method 300 proceeds to operation 306 by exposing the resist film 408 using a pattern that is defined according to the patterned hard mask layer. The exposing process in the operation 306 is one step in a lithography process to form a patterned resist film and is implemented to expose portions of the resist film 408 located on the hard mask features, resulting in exposed resist features 410, such as 410a-c. In one embodiment, the operation 306 includes exposing the resist film 408 by a radiation energy using a photomask 450 (or a mask or reticle) having a pattern defined thereon. In the present example, the photomask 450 is a binary mask (BIM) and includes a transparent substrate 452 and an opaque layer 454 disposed on the transparent substrate 452. The opaque layer 454 is patterned with various openings, such as 456a through 456c, such that the radiation energy can be directed to the resist film 408 during the exposing process.

In various embodiments, the radiation energy includes ultraviolet (UV) I-line light, deep ultraviolet (DUV) light, extreme ultraviolet (EUV) light, or X-ray tool. In other embodiments, the photomask may be a phase shift mask (PSM). The phase shift mask may be an alternative phase shift mask (alt. PSM) or an attenuated phase shift mask (att. PSM). In another embodiment where EUV is used, the photomask may be reflective. In an alternative embodiment, the exposing process in the operation 306 may eliminate the photomask but utilize radiation beam to directly write the resist film 408 according to a predefined pattern. For example, an electron beam in an electron beam writer or an ion beam in an ion beam writer may be used for the exposing process. The exposed resist features 410 are defined according to the exposure pattern (such as the pattern defined in the photomask 450) such that the final patterned resist film has a surface profile with reduced height difference. Eventually, the hard mask features are be effectively removed at a later stage of the method 300. In one embodiment, the exposed features are positioned on at least a subset of the hard mask features. In the present embodiments, the dimension of an opening of the opaque layer 454 in the photomask 450 depends on the dimension of the corresponding material feature with a hard mask feature deposited thereon. State differently, the dimension of an opening of the opaque layer 454 in the photomask 450 depends on the dimension of the corresponding hard mask feature. Here the dimension refers to a horizontal dimension. For example, the dimension of the opening 456a is Wp and the dimension of the material feature 404a is Wm as illustrated in FIG. 9. In one example, the dimension of the opening equals to the dimension of the corresponding material feature minus a first predetermined value from each side of the material feature. In a particular example, the first predetermined value also depends on the dimension of the material feature. The first predetermined value may depend on the exposing tool to perform the exposing process, resist type of the resist film 408, the substrate material, the characteristics of the etching back process of the subsequent operation, or a combination thereof. The first predetermined value will be discussed in more detail below. The dimension of the opening defined in the opaque layer 454 decreases when the dimension of the corresponding material feature decreases.

When the dimension of the material feature is less than a second predetermined value, the corresponding opening in the opaque layer 454 on the corresponding hard mask feature is not exposed or no opening is defined in the opaque layer 454. The second predetermined value is used as a criterion to categorize the material features with a subset of the material features such that no exposed features are formed on those material features in the first subset. The second predetermined value also depends on the exposing tool, the resist type, the substrate material, and/or the etching back process.

In some embodiments, an exposed feature may be a full exposed feature. The full exposed feature is totally removed by a developing process and an opening is formed in the resist film 408 with the corresponding hard mask feature uncovered.

In another embodiment, an exposed resist feature is a partial exposed resist feature because of the radiation diffraction. After a developing process, the partial exposed resist feature may be converted to a smaller opening in the resist film with a dimension less than the dimension of the opening of the opaque layer 454 defined in the photomask, according to one example. In another example where the opening defined in the photomask is a sub-resolution feature, the partial exposed resist feature may not be converted to an opening in the resist film. Instead, the thickness of the exposed resist feature is reduced. By reducing the thickness of the resist film over the hard mask feature, it helps to remove the hard mask feature in an etch-back process. A sub-resolution feature in a photomask is a feature beyond the minimum resolution limit of the exposing tool.

As an example illustrated in FIG. 9, the exposed features 410a-c are formed over the hard mask features 406a-c respectively using a mask 450. The hard mask features 406a-d are disposed on the material features 404a-d respectively. Dimensions of the exposed features 410a-c depend on dimension of the material features 404a-d respectively. The dimensions of the openings 456a-c equal the dimensions of the material features 404a-c minus the first predetermined value from each side of the material features 404a-c, respectively. The first predetermined value also depends on dimension of the material features 404a-c. In one example where a material feature has a dimension ranges between about 0.23 and about 0.24 μm, the first predetermined value ranges from approximate 0 to 0.05 μm. The resist film over the hard mask feature 406d is not exposed when the dimension of the material feature 404d is smaller than the second predetermined value. The second predetermined value may change. In one example, the second predetermined value is 0.11 μm.

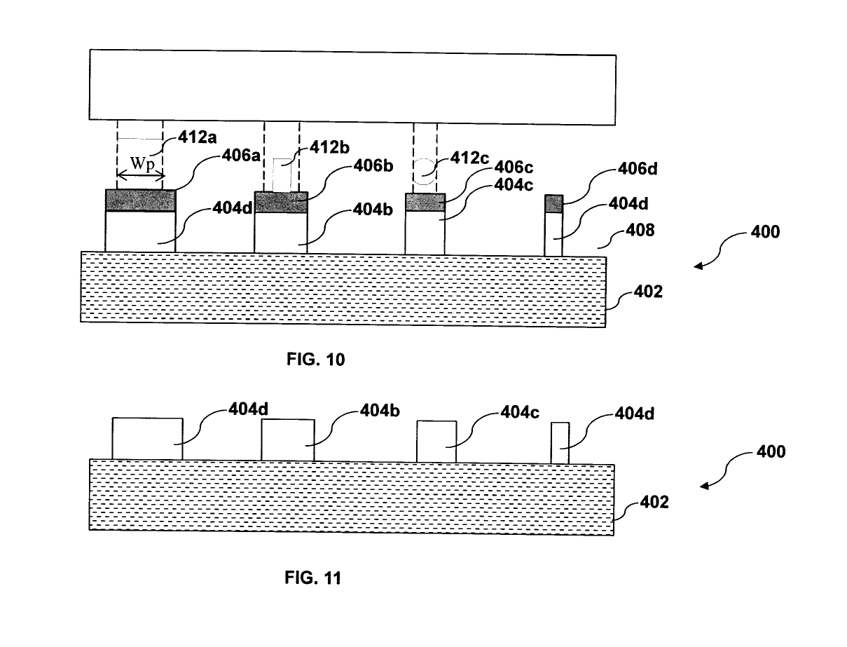

Referring to FIGS. 7 and 10, the method 300 proceeds to operation 308 by developing the resist film to form an opening or partially opening in the resist film over the hard mask features. The operation 308 includes applying a developer, for example, tetra-methyl ammonia hydroxide (TMAH), on the exposed resist film. The operation 308 may further include a post expose bake (PEB), a post develop bake (PDB), or both. The operation 308 may also include a rinse process to wash away resist residues. As an example illustrated in FIG. 10, openings 412a-b are formed in the resist film 408 over the hard mask feature 406a-b respectively. Particularly, the resist film over the hard mask feature 406c has a reduced thickness but no opening is formed, referred to as a sub-resolution resist feature 412c as it is associated with the sub-resolution feature 456c defined on the photomask 450.

As shown in FIGS. 9 and 10, dimension of the opening 412a is equal to dimension of the associated mask feature 456a and dimension of opening 412b is smaller than dimension of the associated mask feature 456b. Also as shown in FIG. 10 the sub-resolution resist feature 412c is not totally opened to reach the hard mask feature 406c. However, thickness of the resist over the hard mask feature 406c is reduced. The reduced thickness of the resist or resist loss can also help to remove the hard mask feature 406c in late etching back process. The above description assumes the resist film is a positive resist. In another embodiment where a negative resist film is used, the exposure pattern defined in the photomask (or in the database for direct write) is reversed. For example, the opening in the opaque layer 454 for the positive resist is an opaque island in the opaque layer 454 for the negative resist, and an opaque feature in the opaque layer 454 for the positive resist is an opening in the opaque layer 454 for the negative resist.

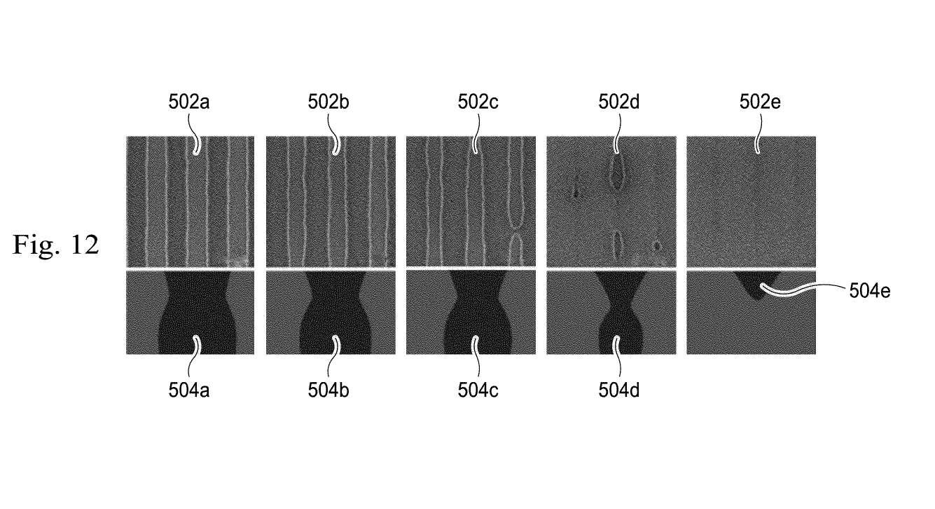

Referring to FIGS. 7 and 11, the method 300 proceeds to operation 310 by etching back the resist film 408 and the patterned hard mask layer 406. The operation 310 may include using a dry plasma etching process, or a wet chemical etching process, or both. The operation 310 may include a cleaning process. In an alternative embodiment, the operation 310 includes a first step to etch back the resist film and a second step to remove the hard mask layer 406.

By implementing the operations of the method 300, the material layer 404 is patterned. Especially, the material layer 404 is patterned using the hard mask layer 406 and the hard mask layer 406 is effectively removed afterward. Additional operations may be performed before, during, and after the method 300.

FIG. 12 includes a top portion and a bottom portion. The top portion of FIG. 12 includes scanning electron microscope (SEM) top-view images of a resist film after a developing process. The bottom portion of FIG. 12 includes simulation profiles of the resist film after the developing process. The FIG. 12 is provided as one example to illustrate the resist film after the developing operation in the method 300. Openings 502a-d are formed in the resist film and profile features 504a-d are associated simulation profiles of the openings 504a-d. Resist in the opening 502a is removed by the developing process, and the profile feature extends through the resist film. Dimension of the opening 502a is equal to a designed dimension (defined in the photomask). Resist in the openings 502b-d is removed by a developing process, profile features 504b-d extends through the resist film, and dimensions of the openings 502b-d are smaller than the designed dimensions. Resist is not totally removed in a feature 502e by a developing process, and a profile feature 504e does not extend through the resist film. The opening 502a is referred to as a full opening, the openings 502b-d are referred to as partial openings, and the feature 502e is referred to a sub-resolution resist feature.

In foregoing discussion, a full opening feature or a partial opening feature over the hard mask feature is formed using an exposing tool, in one embodiment, the exposing tool includes an optical exposing tool where a mask is utilized.

In the method, the exposure pattern used in the exposing process is defined according to the pattern defined in the material layer 404 (or the hard mask layer 406). In this consideration, the patterned resist film 408 has various openings to uncover the underlying hard mask features such that the hard mask layer can be effectively removed in the later operation. Especially, whether an opening is formed or not, is partial or full and what the dimension of an opening is are determined according to various rules regarding the dimension of the respective hard mask feature (or material feature).

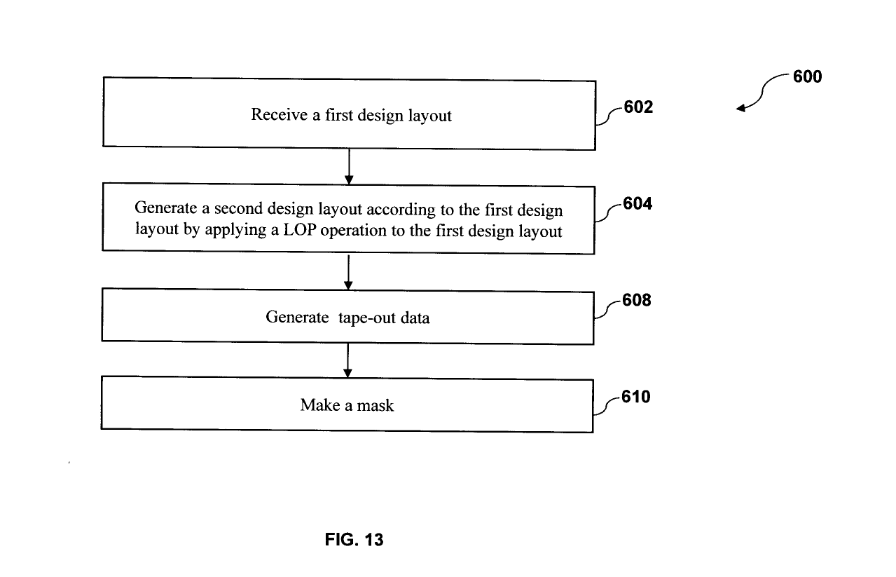

FIG. 13 is a flow chart of a method 600 for fabricating a photomask to be used in the exposing process of the method 300 constructed according to aspects of the present disclosure in one or more embodiments. The method 600 begins at operation 602 by receiving a first IC design layout (or first design layout) from a designer. The designer can be a separate design house or can be part of a semiconductor fabrication facility (fab) for making IC productions according to the IC design layout. In various embodiments, the semiconductor fab may be capable of making photo-masks, semiconductor wafers, or both. In the present embodiment, the first design layout defines a pattern for a material layer to be formed on the semiconductor substrate. In furtherance of the embodiment, the first design layout defines a pattern to be formed in the material layer 404 in FIG. 8. The first design layout is used to pattern the material layer 404 to form various material features using the hard mask layer 406 either by a photolithography process with a first photomask or by direct write with e-beam or ion-beam.

The method 600 proceeds to operation 604 by generating a second design layout according to the first IC design layout. Especially, the second design layout is used to pattern the resist film 408 over the patterned material layer 404 while the first design layout is used to pattern the material layer 404. In this case, the second design layout is generated according to the first design layout and is to be formed in a second photomask. In the present embodiment, the second design layout is generated by applying a logic operation (LOP) to the first design layout.

In one embodiment, various subsets of features (for openings, or simply referred to as openings) in the first design layout are categorized according to dimensional rules. In one embodiment, three subsets are identified, each having different sizes. In one example, a first subset of features each have a size in a first range, a second subset of features each have a size in a second range, and a third subset of features each have a size in a third range. The three ranges collectively cover various sizes of the features in the first design layout. The features in the first subset have sizes less than those of the features in the second subset. The features in the second subset have sizes less than those of the features in the third subset. In this example, the first subset of features are eliminated from the second design layout, the second subset of features are mapped to the second design layout but with sizes less than the minimum resolution limit. In other words, sub-resolution features are generated in the second design layout according to the second subset of features. The third subset of features are mapped to the second design layout with certain offsets. In another example, the third subset of features are further categorized into two subsets, one with lithography related bias and another without such bias.

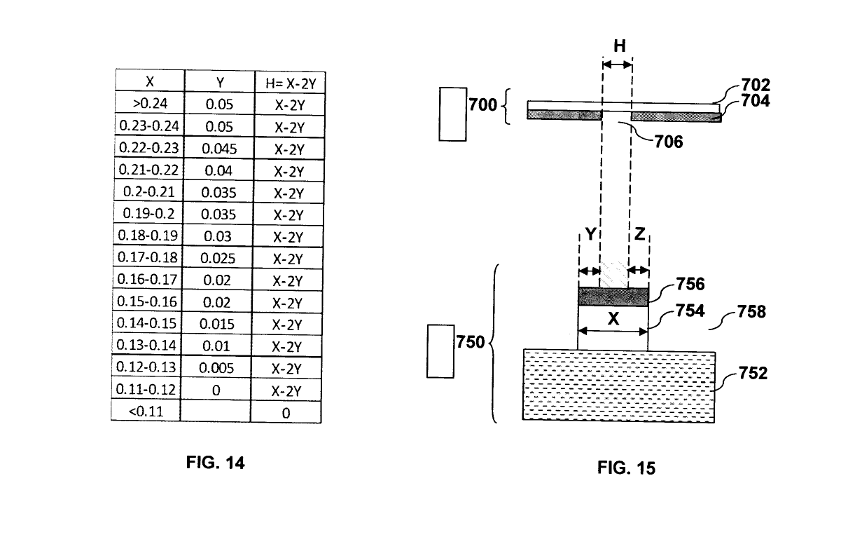

FIG. 14 includes a table constructed according one embodiment. The table includes three columns for parameters X, Y and H, respectively. X represents the dimension of a feature in the first design layout, H represents the dimension of the corresponding feature in the second design layout, Y is the offset to be applied when generating the corresponding feature in the second design layout according to the feature in the first design layout. In the present example, the LOP includes applying the offset Y to X to generate the corresponding feature in the second design layout with a dimension H=X−2Y. Particularly, the feature in the second design layout has an offset Y from each side. In this embodiment, when the dimension X is greater than approximate 0.24 μm, the dimension H equals to X−2Y (Y=0.05 μm). When the dimension X is smaller than approximate 0.11 μm, the dimension H equals to zero. In another words, no corresponding feature is generated in the second design layout when the dimension is smaller than 0.11 μm. When the dimension X is approximate between 0.11 and 0.24 μm, the dimension H equals X−2Y (Y varying with the dimension X). For example, Y varies from approximate 0.05 to 0 μm when the dimension X changes from approximate 0.24 to approximate 0.11 μm.

Referring back to FIG. 13, after the second design layout is generated by applying a LOP to the first design layout at the operation 604, the method 600 proceeds to operation 606 by generating a tape-out data for a mask shop. The method 600 may proceed to operation 608 by making a photomask on a mask substrate using a mask writer, such as an electron beam writer, an ion beam writer, or a laser beam writer. The operation 608 includes fracturing the tape-out data into a plurality of essential rectangles or trapezoids for a mask writer.

In a different perspective, the second design layout can be generated based on the patterned material layer 404. In the present embodiments, the LOP includes identifying a material feature in the patterned material layer 404. The LOP also includes generating a feature in the second design layout according to the material feature. The LOP also includes assigning a value to dimension of the feature in the first design layout based on dimension of the corresponding feature in the first design layout. In the present embodiments, the dimension of the feature in the second design layout is a function of dimension of the material feature. The assigned value may change with the dimension of the material feature, the characteristics of the resist film 408, and an exposing tool to pattern the resist film according to the second design layout.

Thus generated photomask has a pattern related to the patterned material layer. In one particular embodiment illustrated in FIG. 15, which is a portion of FIG. 9 in one example. The photomask 700 also includes a mask substrate 702 and an opaque layer 704. The photomask 700 includes a mask feature 706 with a dimension H. The semiconductor structure 750 includes a substrate 752, a material feature 754, a hard mask feature 756 and a resist film 758. The dimension X of the material feature 754 is illustrated in FIG. 15. In the present embodiments, the dimension H of the mask feature 706 depends on the dimension X of the material feature 754. The dimension H of the mask feature 706 equals to the dimension X of the material feature 754 minus a predetermined value Y from one side of the material feature 754 and minus a predetermined value Z from another side of the material feature 754. The predetermined value Y or the predetermined value Z also depends on the dimension X of material feature 754. In some embodiments, the predetermined value Y or the predetermined value Z may have the same value. In the present embodiments, a photomask may have a 4× or 5× magnification, and a dimension is referred to as a dimension printed on a substrate.

Thus, the present disclosure provides one embodiment of a method that includes providing a substrate having a patterned material layer and a patterned hard mask layer disposed on the patterned material layer, wherein the patterned material layer includes a material feature having a first dimension and the patterned hard mask layer includes a hard mask feature covering the material feature. The method also includes forming, on the substrate and the hard mask feature, a patterned resist layer with an opening that exposes the hard mask feature and has a second dimension as a function of the first dimension; etching back the resist film; and removing the patterned hard mask layer.

The present disclosure also provides another embodiment of a method that includes providing a substrate having a patterned material layer and a patterned hard mask layer disposed on the patterned material layer, wherein the patterned material layer includes a material feature and the patterned hard mask layer includes a hard mask feature covering the material feature. The method further includes depositing a resist film on the substrate and the hard mask feature; exposing the resist film according to an exposure pattern having a sub-resolution feature associated with the material feature such that a portion of the resist film over the hard mask feature is partially exposed; etching back the resist film; and removing the patterned hard mask layer.

The present disclosure also provides another embodiment of a method that includes receiving an integrated circuit (IC) design layout having a first pattern to be formed in a first material layer on a semiconductor substrate; generating a second pattern according to the first pattern by performing a logic operation (LOP) to the first pattern, wherein the second pattern is to be formed in a second material layer on the semiconductor substrate; and generating a tape-out data from the second pattern for mask making.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
providing a substrate having a patterned material layer and a patterned hard mask layer disposed on the patterned material layer, wherein the patterned material layer includes a material feature having a first dimension and the patterned hard mask layer includes a hard mask feature covering the material feature;
forming, on the substrate and the hard mask feature, a patterned resist layer with an opening that exposes the hard mask feature and has a second dimension as a function of the first dimension;
etching back the resist layer; and
removing the patterned hard mask layer.

2. The method of claim 1, wherein the forming, on the substrate and the hard mask feature, a patterned resist layer includes:
coating a resist layer on the substrate and the patterned hard mask layer;
exposing the resist layer according to a pattern having a feature to define the opening; and
applying a developing process to the resist layer to form the patterned resist layer having the opening.

3. The method of claim 1, wherein the first dimension equals to the second dimension minus a first predetermined value from a first side of the material feature and minus a second predetermined value from a second side of the material feature.

4. The method of claim 3, wherein each of the first predetermined value and the second predetermined value is a function of the second dimension.

5. The method of claim 3, wherein the second predetermined value equals to the first predetermined value.

6. The method of claim 2, wherein the second dimension is a sub-resolution dimension so that the resist layer associated with the opening has a partial film loss during the forming of the patterned resist layer.

7. The method of claim 1, wherein the second dimension is zero when the second dimension is smaller than a third predetermined value.

8. A method, comprising:
providing a substrate having a patterned material layer and a patterned hard mask layer disposed on the patterned material layer, wherein the patterned material layer includes a material feature and the patterned hard mask layer includes a hard mask feature covering the material feature;
depositing a resist film on the substrate and the hard mask feature;
exposing the resist film according to an exposure pattern having a sub-resolution feature associated with the material feature such that a portion of the resist film over the hard mask feature is partially exposed;
etching back the resist film; and
removing the patterned hard mask layer.

9. The method of claim 8, wherein
the exposure pattern having a sub-resolution feature is defined in a photomask; and
the exposing the resist film includes exposing the resist film using the photomask.

10. The method of claim 9, wherein the exposing the resist film includes exposing the resist film through the photomask in a lithography system having a resolution limit, wherein the sub-resolution feature has a first dimension less than the resolution limit.

11. The method of claim 10, wherein
the material feature includes a second dimension; and
the first dimension is a function of the second dimension.

12. The method of claim 11, wherein
the exposure pattern further includes a resolvable feature having a third dimension greater than the resolution limit;
the patterned material layer further includes a second material feature that has a fourth dimension greater than the second dimension;
the patterned hard mask layer further includes a second hard mask feature covering the second material feature; and
the exposing the resist film includes exposing the resist film according to the exposure pattern such that an opening is formed in the resist film and the second hard mask feature is at least partially uncovered by the resist film.

13. The method of claim 8, wherein the providing of the substrate includes
forming a material layer on the substrate;
forming the patterned hard mask layer on the material layer; and
etching the material layer through openings of the patterned hard mask layer to form the patterned material layer.

14. The method of claim 8, further comprising, after the exposing of the resist film, developing the resist film such that the portion of the resist film over the hard mask feature is thinned.

15-20. (canceled)

21. A method, comprising:
providing a substrate having a patterned material layer and a patterned hard mask layer disposed on the patterned material layer, wherein the patterned hard mask layer includes a hard mask feature;
forming, on the substrate, a patterned resist layer with an opening that exposes the hard mask feature;
etching back the patterned resist layer; and
removing the patterned hard mask layer.

22. The method of claim 21, wherein the forming a patterned resist layer includes:
coating a resist layer on the substrate and the patterned hard mask layer;
exposing the resist layer according to a pattern having a feature to define the opening; and
applying a developing process to the resist layer to form the patterned resist layer having the opening.

23. The method of claim 21, wherein the patterned material layer includes a material feature having a first dimension and the opening has a second dimension,
wherein the first dimension equals to the second dimension minus a first predetermined value from a first side of the material feature and minus a second predetermined value from a second side of the material feature.

24. The method of claim 23, wherein each of the first predetermined value and the second predetermined value is a function of the second dimension.

25. The method of claim 23, wherein the second predetermined value equals to the first predetermined value.

26. The method of claim 23, wherein the second dimension is a sub-resolution dimension so that the resist layer associated with the opening has a partial film loss during the forming of the patterned resist layer.
